(19) United States
(12) Patent Application Publication
(10) Pub. No.: US 2026/0043965 A1
(43) Pub. Date: Feb. 12, 2026

(54) Planar Lightwave Circuit Lattice Filter and Optical Transmitter Module Using Thereof

(71) Applicants: Nippon Telegraph and Telephone Corporation, Tokyo (JP); NTT Innovative Devices Corporation, Yokohama-shi, Kanagawa (JP)

(72) Inventors: Ai Yanagihara, Musashino-shi, Tokyo (JP); Kenya Suzuki, Musashino-shi, Tokyo (JP); Shigeru Kanazawa, Musashino-shi, Tokyo (JP); Yasuhiko Nakanishi, Musashino-shi, Tokyo (JP); Manabu Oguma, Yokohama-shi, Kanagawa (JP)

(21) Appl. No.: 18/998,202

(22) PCT Filed: Aug. 31, 2023
(86) PCT No.: PCT/JP2023/031915

§ 371 Date: Jan. 24, 2025

(30) Foreign Application Priority Data
Aug. 31, 2022 (JP) 2022-137717

(51) Int. Cl. G02B 6/293; G02B 6/12

(52) U.S. Cl. CPC G02B 6/29368; G02B 6/12016; G02B 6/12021; G02B 6/12033; G02B 6/2938; G02B 2006/12159

(57) ABSTRACT

An embodiment of the present disclosure provides a planer-lightwave-circuit filter with low loss and a filter shape with a high degree of rectangularity. A planer-lightwave-circuit filter for multiplexing signal-light beams of different wavelengths includes input waveguides, a multiplex circuit, and at least one output waveguide. The multiplex waveguide has an asymmetric MZI circuit cascaded in stages. The asymmetric MZI circuit has an input-side coupler, an output-side coupler, and two waveguides connecting an output of the input-side coupler to an input of the output-side coupler and having an optical path length difference. Two of the input waveguides are connected to inputs of the input-side coupler of each MZI circuit arranged in a first stage. The planer-lightwave-circuit filter is configured so that a signal-light beam in which the signal-light beams output from the output-side coupler of the MZI circuit arranged in a final stage are multiplexed is coupled to the output waveguides.

### TECHNICAL FIELD

The present disclosure relates to a planer lightwave circuit filter and an optical transmitter module using the planer lightwave circuit filter.

### BACKGROUND ART

As data communication becomes faster and increases in capacity, an optical communication device and an optical interconnection technique become more sophisticated. The optical communication device does not use an element with a single function such as a conventional laser diode (LD), a photo-diode (PD), and an optical waveguide filter as it is, but combines these elements and accommodates the elements into one package (that is, a plurality of elements are integrated into one module) to realize multi-channels, multi-functions, and high-functionality devices.

The extension of a communication distance is requested of these modules along with demand for downsizing and cost reduction. For example, 4-ch optical transmitter modules described in NPL 1 and NPL 2 are used for communication whose transmission distance is about 10 km, but are also in growing demand for use in communication whose transmission distance is about 40 km.

For the extension of the transmission distance, a high output of a signal is demanded of a module, and reduction in a loss of a part and an optical coupling portion incorporated into the inside of the modules is demanded.

Further, the extension of the communication distance increases susceptibility to the effect of wavelength dispersion, and therefore propagation light with a wavelength band which is less susceptible to the effect of a dispersive wavelength is used. In that case, wavelength gaps between four signal light beams need to be narrowed, and a multiplexing wave filter to be integrated into a module is required to have a more rectangular transmission spectrum property.

A multi-channel optical transmitter module is provided with an MUX filter to multiplex a signal light beam output from each LD. It has been reported that a multi-layer membrane crystal thin film filter (TFF) (see NPL 1) is used as this multiplex filter, and a structure in which a planer lightwave circuit AWG is used (see NPL 2) as this multiplex filter is reported. Given that the number of channels implemented in the multi-channel optical transmitter module is increased from this time on, a planer lightwave circuit type in which loss in each signal channel is less uneven is advantageous.

FIG. 1 is a diagram illustrating a schematic configuration of a 4-ch optical transmitter module using a conventional planer lightwave circuit filter, and FIG. 1(a) is a top view and FIG. 1(b) is a cross-sectional view. As shown in FIG. 1, in an optical transmitter module 100, four LDs 102 and a Planar Lightwave Circuit (PLC) 110 are arranged on an upper surface side of a main surface (XY surface) of a base 101 and are accommodated in a package 107 (e.g. a ceramic butterfly package for hermeticity). A Thermoelectric Controller (TEC) 109 is arranged between a lower surface of the base 101 and the package 107. The package 107 is connected to a sleeve 121 having an optical fiber 120 and a lens 122.

An LD 102 is arranged on an electric circuit 108 arranged on the upper surface of the base 101. The electric circuit 108 is a circuit to drive the LD 102. The center wavelengths λ0 to λ3 of the four LDs 102-0 to 102-3 are different from one another. For example, a wavelength band of S-band is used in an optical transmitter module for an access system.

Between the LDs 102 and the PLC 110, four pairs of lenses 103a and 103b corresponding to the four LDs 102 are arranged. Light from the LD 102 is condensed by the lens 103b and coupled to an input waveguide 111 after converted into a collimate light beam by the lens 103a. That is, optical coupling in a parallel luminous flux system is performed between the LDs 102 and the PLC 110.

A beam splitter 104 is arranged between the lens 103a and the lens 103b. A monitor PD (MPD) 105 to monitor light from the LD102 is arranged on an upper surface of the beam splitter 104. Part of light from the LD102 is branched by the beam splitter 104 arranged between the lens 103a and the lens 103b and received by the monitor PD 105.

The PLC 110 is provided with the input waveguide 111, an Arrayed Waveguide Grating (AWG) 113, and an output waveguide 112 and functions as an AWG planer lightwave circuit multiplexer (MUX) filter. For example, a light beam having a wavelength λ0, a light beam having a wavelength λ1, a light beam having a wavelength λ2, and a light beam having a wavelength λ3 from the LDs 102-0, 102-1, 102-2 and 102-3 incident from the input waveguides 111-0, 111-1, 111-2, and 111-3 on the planer lightwave circuit are multiplexed through the AWG 113 and exit from the output waveguide 112 near an output-side end surface of the PLC 110.

The output-side end surface of the PLC 110 is provided with a lens 103c, and, an isolator 106 is arranged ahead of the lens 103c. The multiplexed light is guided through the output waveguide 112 and is optically-coupled to an optical fiber 120 through the lens 103 provided on the end surface of the PLC 110, the isolator 106, and a lens 122. Also, optical coupling in a parallel luminous flux system is performed between the PLC 110 and the optical fiber 120 by the lens 103c and the lens 122.

### CITATION LIST

### Patent Literature (PTL)

PTL 1: Japanese Patent Laid-Open No. 2014-59542

### Non Patent Literature (NPL)

NPL 1: S. Kanazawa et al., “High Output Power and Compact LAN-WDM EADFB Laser TOSA for 4×100-Gbit/s/λ 40-km Fiber-Amplifier-Less Transmission,” 2020 Optical Fiber Communications Conference and Exhibition (OFC), 2020, pp. 1-3

NPL 2: J. Liu, Q. Huang and J. Xia, “High Assembly Tolerance and Cost-Effective 100-Gb/s TOSA With Silica-PLC AWG Multiplexer,” in IEEE Photonics Journal, vol. 11, no. 4, pp. 1-9, August 2019, Art no. 7904909, doi: 10.1109/JPHOT.2019.2924035

### SUMMARY OF INVENTION

With reference to FIG. 1, the aforementioned optical transmitter module using the planer lightwave circuit filter mainly has the following three problems:
Problem 1: A low loss of the AWG planer lightwave circuit filter installed in the optical transmitter module is demanded to extend the transmission distance. Further, a wavelength arrangement of each signal is narrowed, and thus making rectangularity of a transmission spectrum shape (hereinafter referred to as filter shape) indicating a property of a filter higher is demanded. There is a problem that the planer lightwave circuit filter provided with a single AWG has a high loss and a low degree of rectangularity.
Problem 2: To downsize an optical transmitter module, the downsizing of a chip (PLC) incorporated inside is also demanded. However, there is a problem that an AWG provided with a plurality of waveguides of different lengths between two slab waveguides has a large occupancy area in the PLC and thus the downsizing of the chip has a limitation. Further, if a Mach-Zehnder interferometer (MZI) circuit connected to the AWG or the like is arranged on the PLC to make rectangularity of a filter shape higher, the size of the chip (PLC) becomes larger.
Problem 3: For a low cost and simplification of an implementation step, the reduction of parts to be installed in an optical transmitter module is demanded. For example, as mentioned above with reference to FIG. 1, the beam splitter 104 to monitor the intensity of the light from the LD 103 is arranged. By installing the beam splitter 104, the number of parts to be installed in the optical transmitter module increases, costs rise, and the degree of difficulty of the implementation step becomes higher. Further, there is a problem that the need for lengthening the optical length between the LD 102 and the PLC 110 is a disadvantage for the downsizing of the optical transmitter module.

The present disclosure is made in the light of these problems, and the purpose is to provide a planer lightwave circuit filter with a low cost and a high degree of rectangularity of a filter shape. Further, the present disclosure provides a small planer lightwave circuit filter. Furthermore, the present disclosure provides a planar lightwave circuit filter in which the number of parts can be reduced.

An embodiment of the present disclosure is a planer lightwave circuit lattice filter for multiplexing a plurality of signal light beams of different wavelengths and includes a plurality of input waveguides receiving input of the plurality of signal light beams, a multiplex circuit multiplexing the plurality of signal light beams, and at least one output waveguide outputting a multiplexed signal, the multiplex circuit having an asymmetric MZI circuit cascaded in multiple stages, the asymmetric MZI circuit including an input-side coupler, an output-side coupler, and two waveguides which connect an output of the input-side coupler to an input of the output-side coupler and to which an optical path length difference is given, wherein two of the plurality of input waveguides are connected to inputs of the input-side coupler of each asymmetric MZI circuit arranged in a first stage, and the planer lightwave circuit lattice filter is configured so that a signal light beam in which the plurality of signal light beams output from the output-side coupler of the one asymmetric MZI circuit arranged in a final stage are multiplexed is coupled to the output waveguide.

According to an embodiment of the present disclosure, it is possible to provide a planer lightwave circuit lattice filter having a lower loss and higher rectangularity filter performance compared with a loss and rectangularity filter performance of the AWG planer lightwave circuit filter. Further, according to an embodiment of the present disclosure, it is possible to provide a planer lightwave circuit lattice filter in which a chip (PLC) can be downsized. Furthermore, according to an embodiment of the present disclosure, it is possible to provide a planer lightwave circuit lattice filter in which the number of parts can be reduced.

### BRIEF DESCRIPTION OF DRAWINGS

FIG. 1 is a diagram illustrating a schematic configuration of a 4-ch optical transmitter module using a conventional arrayed waveguide grating planer lightwave circuit filter is used, and FIG. 1(a) is a top view and FIG. 1(b) is a cross-sectional view.

FIG. 2 is a diagram illustrating a schematic configuration of a 4-ch optical transmitter module using a planer lightwave circuit lattice filter of one embodiment of the present disclosure. FIG. 2(a) is a top view and FIG. 2(b) is a cross-sectional view.

FIG. 3 is a diagram illustrating a schematic configuration of a planer lightwave circuit lattice filter of an embodiment of the present disclosure.

FIG. 4 is a diagram illustrating a schematic configuration of a planer lightwave circuit lattice filter of an embodiment of the present disclosure.

FIG. 5 is a diagram illustrating a schematic configuration of a planer lightwave circuit lattice filter of an embodiment of the present disclosure.

FIG. 6 is a diagram illustrating a schematic configuration of a planer lightwave circuit lattice filter of an embodiment of the present disclosure.

### DESCRIPTION OF EMBODIMENTS

Hereinafter, embodiments of the present disclosure are explained in detail with reference to the drawings. Identical or similar reference numerals denote identical or similar elements, and a repetitive explanation may be omitted. Numerical values in the following explanations are examples, and the present disclosure may be carried out by using other numerical values without departing the scope of the present disclosure.

Planer lightwave circuit lattice filters of various embodiments explained below are planer lightwave circuit lattice filters to multiplex N signal light beams of different wavelengths, where Nis an integer equal to or more than 2, and may include N input waveguides receiving input of N signal light beams, a multiplex circuit multiplexing N signal light beams, and at least one output waveguide outputting a multiplexed signal. The multiplex circuit may include at least N−1 asymmetric MZI circuits cascaded in multiple stages. The asymmetric MZI circuit may include an input-side coupler having one or two inputs and two outputs, an output-side coupler having two inputs and one or two outputs, and two waveguides which connect the two outputs of the input-side coupler to the two inputs of the output-side coupler and to which an optical path length difference is given. Two of the N input waveguides may be connected to two inputs of the input-side coupler of each asymmetric MZI circuit arranged in a first stage. The planer lightwave circuit lattice filters may be configured so that a signal light beam in which the N signal light beams output from the output-side coupler of the asymmetric MZI circuit arranged in a final stage are multiplexed is coupled to the output waveguide.

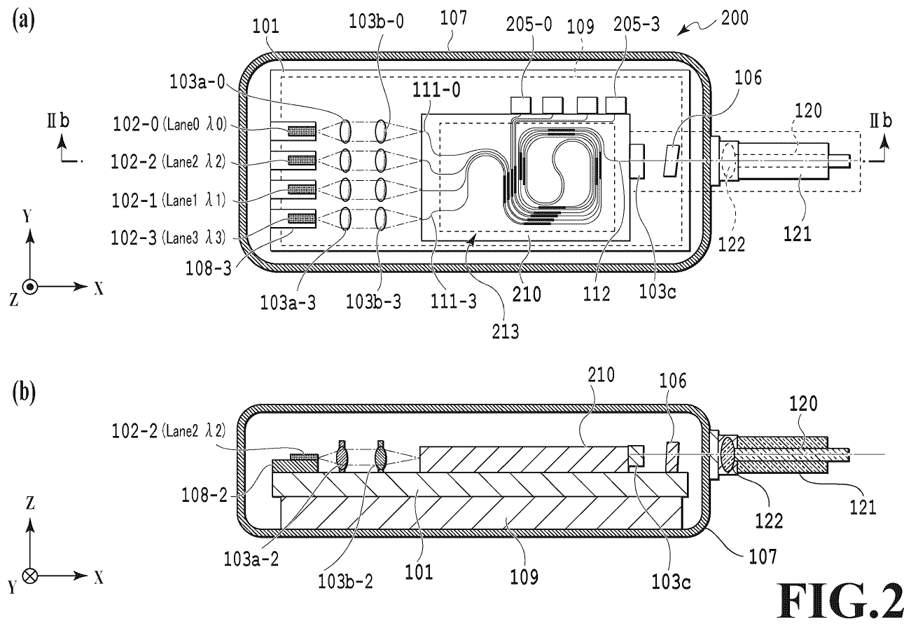

(First Embodiment) With reference to FIGS. 2 to 4, a planer lightwave circuit lattice filter and an optical transmitter module of a first embodiment of the present disclosure are explained. Here, as an example of an optical transmitter module using a planer lightwave circuit lattice filter, a 4-ch TOSA (Transmitter optical sub-assembly) module using a quartz PLC lattice filter is explained. Here, an optical transmitter module of a 4-channel (ch) configuration, that is, an optical transmitter module multiplexing and transmitting four signal light beams of different wavelengths is given as an example, but the number of signal light beams or the number of channels are not limited to 4, and any number may be set.

### Configuration of Optical Transmitter Module

A schematic configuration of an optical transmitter module of an embodiment of the present disclosure is shown in FIG. 2. FIG. 2(a) is a top view and FIG. 2(b) is a cross-sectional view. As shown in FIG. 2, in an optical transmitter module 200, four LDs 102 and PLCs 210 are arranged on an upper surface side of a main surface (XY surface) of a base 101, accommodated in a package 107 (e.g. a ceramic butterfly package for hermeticity), and hermetically sealed. A thermal controller (TEC) 109 is arranged between a lower surface of the base 101 and the package 107. A sleeve 121 having an optical fiber 120 and a lens 122 is connected to the package 107.

An LD 102 is arranged on an electric circuit 108 arranged on the upper surface of the base 101. The electric circuit 108 is a circuit driving the LD 102. The four LDs 102-0 to 102-3 are configured in such a way that transmission wavelengths are different from each other and are LDs outputting light beams of different wavelengths λ0 to λ3 corresponding to Lane 0 to Lane 3 as mentioned above.

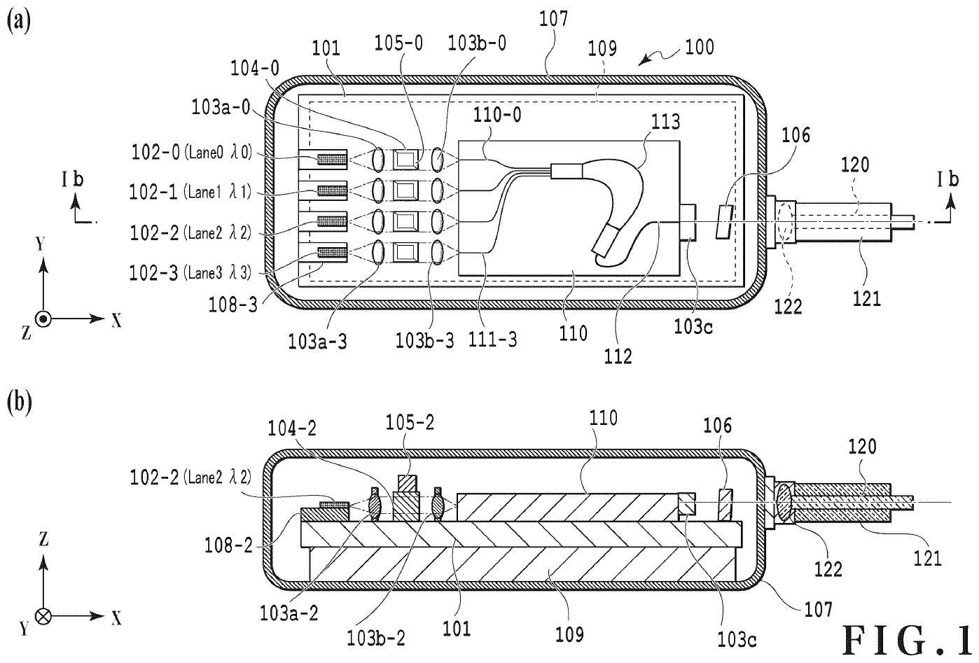

Between the LDs 102 and the PLC 110, four pairs of lenses 103a and 103b corresponding to the four LDs 102 are arranged. After converted into a collimate light beam by the lens 103a, a light beam from the LD 102 is condensed by the lens 103b and coupled to an input waveguide 111. That is, optical coupling in a parallel luminous flux system is performed between the LDs 102 and the PLC 110. Unlike the optical transmitter module 100 of FIG. 1, a beam splitter 104 is not arranged between the lens 103a and the lens 103b. Therefore, it is possible to make the optical length between the LD 102 and the PLC 210 shorter. Incidentally, a spot-size converter may be arranged in the PLC 210 to match the diameter of the light beam condensed by the lens 103b with the input waveguide 111. Further, optical coupling between each LD 102 and the input waveguide 111 of the PLC 110 may be performed in a parallel optical flux system with two lenses as described above or optical coupling may be performed with one lens.

In the optical transmitter module 200, four monitors PD205-0 to 205-3 are arranged on an end surface of a side of the PLC 210. The optical transmitter module 100 of FIG. 1 in which the monitor PD 105 is arranged on the upper surface of the beam splitter 104 is different in this point.

The PLC 210 is a quartz planer lightwave circuit and is provided with the input waveguide 111, a lattice filter 213 composed of a waveguide, and an output waveguide 112. A configuration of the lattice filter 213 will be described later. The planer lightwave circuit lattice filter is configured so that a light beam with the wavelength λ0 from the LD 102-0 is coupled to the input waveguide 111-0, a light beam with the wavelength λ2 from the LD 102-2 is coupled to the input waveguide 111-1, a light beam with the wavelength λ1 from the LD 102-1 is coupled to the input waveguide 111-2, and a light beam with the wavelength λ3 from the LD 102-3 is coupled to the input waveguide 111-3. In the present embodiment, the light beams with the wavelengths λ0, λ1, λ2, and λ3 input into the lattice filter 213 are multiplexed and coupled to the output waveguide 112 and exit from an output-side end surface of the PLC 210. In the present embodiment, the arrangement order of the four LDs 102-0 to 102-3 shown in FIG. 1 is changed to the arrangement order shown in FIG. 2. If the arrangement order of the four LDs 102-0 to 102-3 shown in FIG. 1 is maintained, in the PLC 210, a cross waveguide coupling the input waveguide 111 and the lattice filter 213 may be used.

A lens 103c is provided on the output-side end surface of the PLC 210, and an isolator 106 is arranged ahead of the lens 103c. A multiplexed light beam is guided thorough the output waveguide 112 and is optically-coupled to an optical fiber 120 through the lens 103c arranged on the end surface of the PLC 110, the isolator 106, and the lens 122. By the lens 103c and the lens 122, optical coupling is also performed in a parallel luminous flux system between the PLC 110 and the optical fiber 120. Incidentally, the isolator 106 may be omitted. A spot size converter may be arranged instead of the lens 103c and the lens 122 to match the diameter of the light exiting from the PLC 210 with the diameter of the optical fiber 120. To reduce a reflection return light beam occurring in an end surface of the PLC 210, instead of or in addition to the isolator 106, the PLC 210 in a state in which the end surface is diagonally cut may be used (for example, a shape in which the end surface of the PLC 210 is cut diagonally at around 10 degrees may be used) or the PLC 210 in which an AR coating for the prevention of reflection is applied to the end surface may be used.

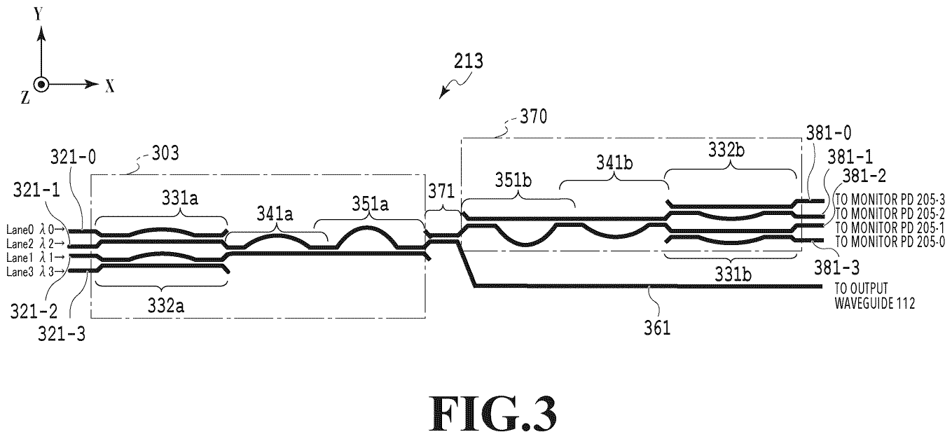

(Configuration of Lattice Filter) Next, with reference to FIG. 3, a planer lightwave circuit lattice filter is explained. FIG. 3 is a diagram illustrating a schematic configuration of the lattice filter 213 composed of a waveguide formed on the PLC 210. As shown in FIG. 3, the lattice filter 213 includes a multiplex circuit 303 connected to four waveguides 321. The waveguides 321-0 to 321-3 are connected to the input waveguides 111-0 to 111-3, respectively.

The multiplex waveguide 303 includes four Mach-Zehnder interferometer (MZI) circuits 331a, 332a, 341a, and 351 cascaded in multiple stages. Each MZI circuit is provided with two couplers each having two inputs and two outputs and two waveguides coupling the two couplers.

The MZI circuit 331a and MZI circuit 332a are arranged in parallel. The MZI circuit 331a and the MZI circuit 332a are cascaded to the MZI circuit 341a. The MZI circuit 341a is cascaded to the MZI circuit 351a. It is decided that a first stage is the MZI circuits 331a and 332a arranged in parallel, a second stage is the MZI circuit 341a, and a third stage is the MZI circuit 351a. An arrangement is performed to make the degree of rectangularity of the filter shape higher by passing through the MZI circuit 351a.

An optical path length difference ΔL is given to the two waveguides coupling two couplers in each MZI circuit. The MZI circuit having the optical path length difference is also referred to as an asymmetric MZI circuit.

A signal light beam λ0 corresponding to Lane 0 and incident from the LD102-0 on the waveguide 321-0 is bifurcated by an input-side coupler of the MZI circuit 331a in the first stage, passed through the two waveguides, multiplexed by an output-side coupler, and output from an lower one of two outputs. A signal light beam λ2 corresponding to Lane 2 and incident from the LD102-2 on the waveguide 321-1 is bifurcated by the input-side coupler of the MZI 331a in the first stage, passed through the two waveguides, multiplexed by the output-side coupler, and output from the lower one of the two outputs. The signal light beams λ0 and λ2 are input to the MZI circuit 341a in the second stage. The signal light beam λ0 is bifurcated by an input-side coupler of the MZI circuit 341a, passed through the two waveguides, multiplexed and branched by an output-side coupler, and output from two outputs. The signal light beam λ2 as well as the signal light beam λ0 is passed through the two waveguides of the MZI circuit 341a in the second stage, and multiplexed and branched by the output-side coupler and output from the two outputs. Further, the signal light beams λ0 and λ2 are input to the MZI circuit 351a in the third stage. The signal light beam λ0 is bifurcated by an input-side coupler of the MZI circuit 351a in the third stage, passed through the two waveguides, multiplexed by an output-side coupler, and output from an upper one of two outputs. The signal light beam λ2 as well as the signal light beam λ0 is bifurcated by the input-side coupler of the MZI circuit 351a in the third stage, passed through the two waveguides, multiplexed by the output-side coupler, and output from the upper one of the two outputs.

The signal light beam λ1 corresponding to Lane 1 and incident from the LD102-1 on the waveguide 321-2 is bifurcated by an input-side coupler of the MZI circuit 332a in the first stage, passed through the two waveguides, multiplexed by an output-side coupler, and output from an upper one of two outputs. A signal light beam λ3 corresponding to Lane 3 and incident from the LD 102-3 on the waveguide 321-3 is bifurcated by an input-side coupler of the MZI 332a in the first stage, passed through the two waveguides, multiplexed by an output-side coupler, and output from the upper one of the two outputs. The signal light beams λ1 and λ3 are input to the MZI circuit 341a in the second stage. The signal light beam λ1 is bifurcated by the input-side coupler of the MZI circuit 341a, passed through the two waveguides, multiplexed and branched by the output-side coupler, and output from the two outputs. The signal light beam λ3 as well as the signal light beam λ1 is passed through the two waveguides of the MZI circuit 341a in the second stage, multiplexed and branched by the output-side coupler and output from the two outputs. Further, the signal light beams λ1 and λ3 are input to the MZI circuit 351a in the third stage. The signal light beam λ1 is bifurcated by the input-side coupler of the MZI circuit 351a in the third stage, passed through the two waveguides, multiplexed by the output-side coupler, and output from the upper one of the two outputs. The signal light beam λ3 as well as the signal light beam λ1 is bifurcated by the input-side coupler of the MZI circuit 351a in the third stage, passed through the two waveguides, multiplexed by the output-side coupler, and output from the upper one of the two outputs.

In this way, the signal light beams λ0 to λ3 incident on the multiplex circuit 303 are multiplexed and output from the upper one of the two outputs of the output-side coupler of the MZI circuit 351a in the third stage. Incidentally. the present embodiment is configured in such a way that part of the signal light beams multiplexed by the multiplex circuit 303 are branched for power monitor use in a coupler 371 and the rest is coupled to the output waveguide 112 through a waveguide 361.

The lattice filter 213 shown in FIG. 3 includes the multiplex circuit 303a and a demultiplex circuit 370 connected via the coupler 371. The demultiplex circuit 370 is provided to separate part of the light beam multiplexed in the multiplex waveguide 303 for each of four wavelengths again and enable the monitor PD to measure power. The configuration of the demultiplex circuit 370 is the same as the configuration of the multiplex circuit 303. The demultiplex circuit 370 and the multiplex circuit 303 are point-symmetrically arranged with respect to the center of the coupler 371. The light beam multiplexed once can be separated into the signals λ0, λ1, λ2, and λ3 again by arranging the demultiplex circuit 370 in this way and can be taken out from an end surface of the PLC (chip) via output waveguides 381-0 to 381-3 connected to the output-side coupler of the MZI circuit 331b and the output-side coupler of the MZI circuit 332b (corresponding to the input-side coupler of the MZI circuit 331a and the input-side coupler of the MZI circuit 332a, respectively). If the arrangement order of the monitors 205-0 to 205-3 is changed. A cross waveguide coupling the waveguide 381 of the lattice filter 213 to the monitor PD 205 may be used.

Since the monitor PD 205 reads power variation of a signal light beam emitted by the LD 102, the branch ratio of the coupler 371 has only to be set so that, for example, a fraction of power of a signal light beam (e.g. 2% or the like) in which the power of a signal light beam which is conveyed to an MPD 295 is multiplexed can be branched.

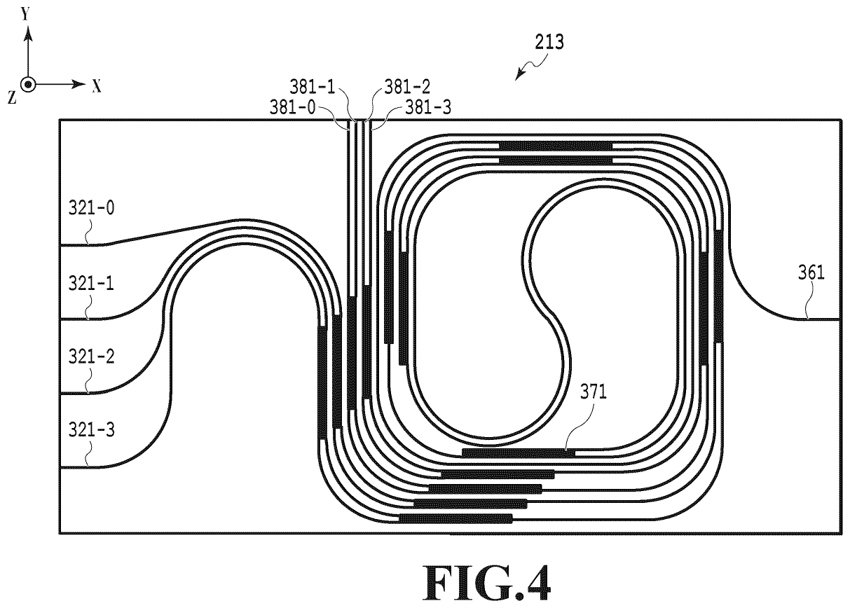

FIG. 4 is a diagram illustrating a schematic configuration of a planer lightwave circuit lattice filter of an embodiment of the present disclosure. FIG. 4 illustrates an example of the arrangement of the lattice filter 213 including the multiplex circuit 303 and the demuliplex circuit 370 connected via the coupler 371 explained with reference to FIG. 3. When a plurality of MZI circuits constituting the lattice filter 213 and cascaded in multiple stages are linearly arranged, an entire circuit length is long. The MZI circuits can be accommodated in a space-saving manner by being coiled and arranged as shown in FIG. 4, and the chip (PLC) can be downsized. Incidentally, when at least either one of the multiplex circuit 303 and the demultiplex circuit 370 is arranged in a coil, the entire circuit length can be made shorter compared with a case where the multiplex circuit 303 or the demultiplex circuit 370 is linearly arranged, and the chip can be downsized.

In the optical transmitter module of the above-mentioned 4-ch configuration, the multiplex circuit 303 multiplexing 4-ch signal light beams (λ0 to λ3) whose wavelengths are different needs to cascade at least three MZI circuits in at least two stages. When N (2 or more)-ch signal light beams (λ0, . . . λ(N−1)) of different wavelengths are multiplexed, a lattice filter has only to be formed by cascading at least N−1 MZI circuits in multiple stages in the multiplex circuit 303 as suggested in PTL 1. Further, the degree of rectangularity of the filter shape can be increased by further cascading the MZI circuits of the lattice filter.

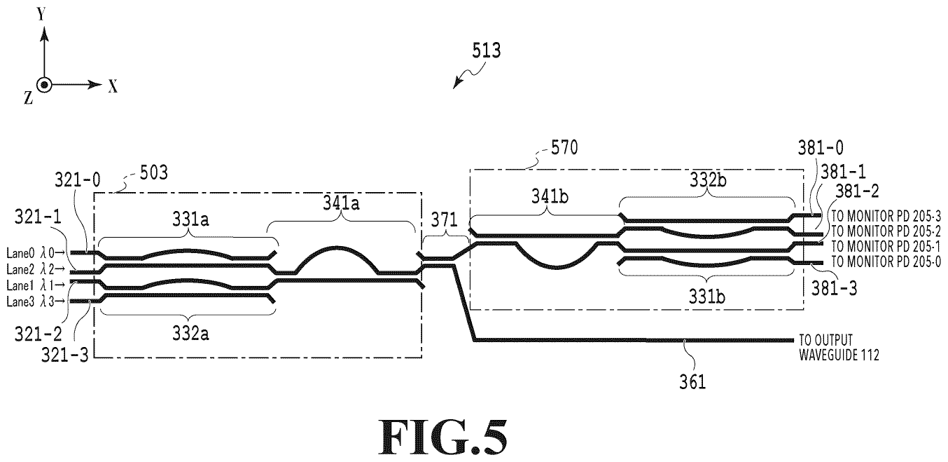

(Second Embodiment) With reference to FIG. 5, a planer lightwave circuit lattice filter and an optical transmitter module of a second embodiment of the present disclosure are explained. FIG. 5 is a diagram illustrating a schematic configuration of a lattice filter 513. The optical transmitter module 200 shown in FIG. 2 may be formed by using the lattice filter 513 as an alternative to the lattice filter 213 shown in FIGS. 3 and 4.

The lattice filter 513 shown in FIG. 5 is provided with a multiplex circuit 503 and a demultiplex circuit 570 connected via the coupler 371. The multiplex circuit 503 is different from the multiplex circuit 303 shown in FIG. 3 in that the multiplex circuit 503 lacks the MZI circuit 351a. Further, the multiplex circuit 570 is different from the demultiplex circuit 370 as shown in FIG. 3 in that the multiplex circuit 570 lacks the MZI circuit 351b. The configurations of MZI circuits constituting the lattice filter 513 are the same as the configurations of the MZI circuits of the demultiplex circuit 370 shown in FIG. 3, and thus the detailed descriptions are omitted. The lattice filter 513 shown in FIG. 5 can also be accommodated in a space-saving manner by being coiled and arranged as shown in FIG. 4, and the chip (PLC) can be downsized.

In the lattice filter 513, the MZI circuit 351a and the MZI circuit 351b are not cascaded and thus the lattice filter 513 is inferior to the lattice filter 213 in the degree of rectangularity of the lattice filter shape, but it is possible to reduce a loss and shorten the circuit length because the number of MZI circuits which are cascaded is smaller.

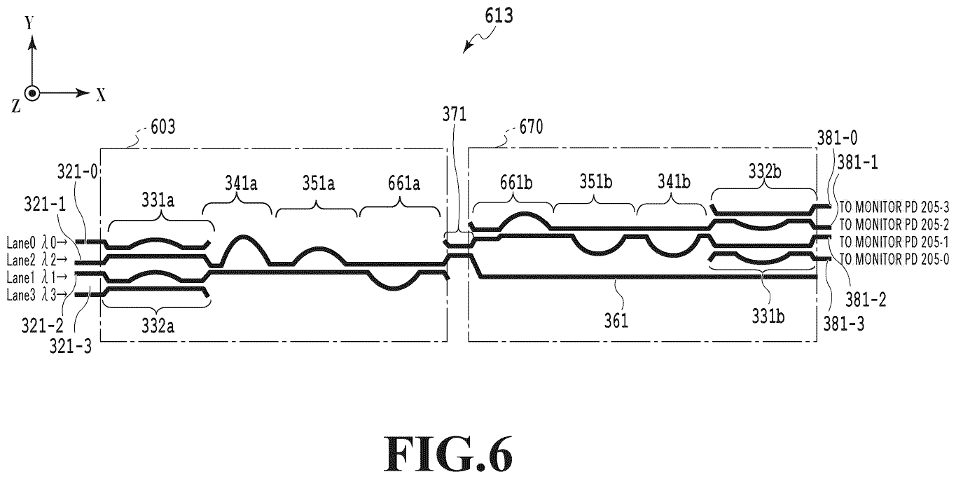

(Third Embodiment) With reference to FIG. 6, a planer lightwave circuit lattice filter and an optical transmitter module of a third embodiment of the present disclosure are explained. FIG. 6 is a diagram illustrating a schematic configuration of a lattice filter 613. The optical transmitter module 200 shown in FIG. 2 may be formed by using the lattice filter 613 as an alternative to the lattice filter 213 shown in FIGS. 3 and 4.

The lattice filter 613 shown in FIG. 6 is provided with a multiplex circuit 603 and a demultiplex circuit 670 connected via the coupler 371. The multiplex circuit 603 is different from the multiplex circuit 303 shown in FIG. 3 in that the multiplex circuit 603 has an MZI circuit 661a in the fourth stage cascaded to the MZI circuit 351a. Further, the demultiplex circuit 670 is different from the demultiplex circuit 370 shown in FIG. 3 in that the demultiplex circuit 670 has an MZI circuit 661b cascaded to the MZI circuit 351b.

In the multiplex circuit 613 of the lattice filter 613, the signal light beam λ0 is bifurcated by the input-side coupler of the MZI circuit 351a in the third stage, passed through the two waveguides, multiplexed and branched by the output-side coupler, and output from the two outputs. The signal light beam λ2 as well as the signal light beam λ0 is bifurcated by the input-side coupler of the MZI circuit 351a in the third stage, passed through the two waveguides, multiplexed and branched by the output-side coupler to provide two outputs. Further, the signal light beam λ0 and the signal light beam λ2 are input to the MZI circuit 661a in the fourth stage. The signal light beam λ0 is bifurcated by an input-side coupler of the MZI circuit 661a in the fourth stage, passed through the two waveguides, multiplexed by the output-side coupler, and output from an upper one of the two outputs. The signal light beam λ2 as well as the signal light beam λ0 is bifurcated by the input-side coupler of the MZI circuit 661a in the fourth stage, passed through the two waveguides, multiplexed by the output-side coupler, and output from the upper one of the two outputs.

In the multiplex circuit 603 of the lattice filter 613, the signal light beam λ1 is bifurcated by the input-side coupler of the MZI circuit 351a in the third stage, passed through the two waveguides, multiplexed and branched by the output-side coupler, and output from the two outputs. The signal light beam λ3 as well as the signal light beam λ1 is bifurcated by the input-side coupler of the MZI circuit 351a in the third stage, passed through the two waveguides, multiplexed and branched by the output-side coupler to provide two outputs. Further, the signal light beams λ1 and λ3 are input to the MZI circuit 661a in the fourth stage. The signal light beam λ1 is bifurcated by the input-side coupler of the MZI circuit 661a in the fourth stage, passed through the two waveguides, multiplexed by the output-side coupler, and output from the upper one of the two outputs. The signal light beam λ3 as well as the signal light beam λ1 is bifurcated by the input-side coupler of the MZI circuit 661a in the fourth stage, passed through the two waveguides, multiplexed by the output-side coupler, and output from the upper one of the two outputs.

In this way, the signal light beams λ0 to λ3 incident on the multiplex circuit 603 are multiplexed and output from the upper one of the two outputs of the output-side coupler of the MZI circuit 661a in the fourth stage. Incidentally, the present embodiment is configured in such a way that part of the signal light beams multiplexed in the multiplex circuit 603 in the coupler 371 are branched for power monitor use and the rest is coupled to the output waveguide 112 through the waveguide 361.

The lattice filter 613 shown in FIG. 6 includes the multiplex circuit 603 and the demultiplex circuit 670 connected via the coupler 371. The demultiplex circuit 670 is provided to separate part of light multiplexed in the multiplex circuit 303 for each of four wavelengths again and measure power in the monitor PD. The configuration of the demultiplex circuit 670 is the same as the configuration of the multiplex circuit 603. The demultiplex circuit 370 and the multiplex circuit 303 are point-symmetrically arranged with respect to the coupler 371. In this point, FIG. 3 is described above and thus an explanation is omitted.

The lattice filter 613 shown in FIG. 6 can be also accommodated in a space-saving manner by being coiled and arranged as shown in FIG. 4, and the chip (PLC) can be downsized.

Compared with the lattice filter 213 shown in FIG. 3 and the lattice filter 413 shown in FIG. 4, the lattice filter 613 shown in FIG. 6 widens the transmission width of a spectrum and can increase a manufacturing margin of the optical transmitter module such as a wavelength accuracy margin.

The degree of the rectangularity of the filter can be enhanced by increasing the number of stages in which MZI circuits are cascaded in the multiplex circuit 603 of the lattice filter 613.

### Industrial Applicability

According to the present disclosure, it is possible to provide a planer lightwave circuit type with a low loss and a high degree of rectangularity of a filter shape. Further, according to the present disclosure, it is possible to provide a small planer lightwave circuit type. Furthermore, according to the present disclosure, it is possible to provide a planer lightwave circuit type in which the number of parts can be reduced.

### Reference Signs List

100, 200 Optical Transmitter Module
101 Base
102 Laser Diode
103, 122 Lens
104 Beam Splitter
105, 205 Monitor PD
106 Isolator
107 Package
108 Electric Circuit
109 TEC
110, 210 PLC
111 Input Waveguide
112 Output Waveguide
113 Arrayed Waveguide Grafting
120 Optical Fiber
121 Sleeve
213, 513, 613 Lattice Filter
303, 503, 603 Multiplex Circuit
370, 570, 670 Demultiplex Circuit
321, 361, 381 Waveguide
331, 332, 341, 351 MZI Circuit
371 Coupler

1. A planer lightwave circuit lattice filter for multiplexing a plurality of signal light beams of different wavelengths comprising:
a plurality of input waveguides receiving input of the plurality of signal light beams;
a multiplex circuit multiplexing the plurality of signal light beams; and
at least one output waveguide outputting a multiplexed signal; wherein
the multiplex circuit has an asymmetric MZI circuit cascaded in multiple stages;
the asymmetric MZI circuit includes:
an input-side coupler;
an output-side coupler; and
two waveguides which connect an output of the input-side coupler to an input of the output-side coupler and to which an optical path length difference is given, wherein
two of the plurality of input waveguides are connected to inputs of the input-side coupler of each asymmetric MZI circuit arranged in a first stage; and
the planer lightwave circuit lattice filter is configured so that a signal light beam in which the plurality of signal light beams output from the output-side coupler of the one asymmetric MZI circuit arranged in a final stage are multiplexed is coupled to the output waveguide.

2. The planner lightwave circuit lattice filter according to claim 1, wherein the input of the input-side coupler of the one asymmetric MZI circuit arranged in the final stage is connected to an output of an output-side coupler of one asymmetric MZI circuit arranged in a stage one stage before the final stage.

3. The planer lightwave circuit lattice filter according to claim 1, further comprising:
a coupler having one input and two outputs and
a demultiplex circuit, wherein
the one input of the coupler is connected to either of two outputs of the output-side coupler of the one asymmetric MZI circuit arranged in the final stage in the multiplex circuit,
one output of the two outputs of the coupler is connected to the output waveguide, and the other output is connected to the demultiplex circuit;
the demultiplex circuit and the multiplex circuit are configured to be point symmetric with respect to the coupler, and
the demultiplex circuit demultiplexes the signal multiplexed by the multiplex circuit into the plurality of signal light beams of different wavelengths and outputs the plurality of signal light beams of different wavelengths.

4. The planer wavelight circuit lattice filter according to claim 3, wherein
at least one of an asymmetric MZI circuit which the multiplex circuit has and which is cascaded in multiple stages and an asymmetric circuit which the demultiplex circuit has and which is cascaded in multiple stages is coiled and arranged.

5. The planer lightwave circuit lattice filter according to claim 4, wherein
the planer lightwave circuit is a quartz planer lightwave circuit.

6. An optical transmitter module used for optical communication comprising:
the planer lightwave circuit lattice filter according to claim 3;
a plurality of light sources outputting the plurality of signal light beams of different wavelengths; and
an optical fiber, wherein
the planer lightwave circuit lattice filter is configured so that a signal light beam in which the plurality of signal light beams guided through the output waveguide are multiplexed is coupled to the optical fiber.

7. The optical transmitter module according to claim 6 further comprising:
a plurality of waveguides to which the plurality of signal light beams of different wavelengths into which the signal multiplexed by the multiplex circuit is demultiplexed by the demultiplex circuit are coupled; and
a plurality of light-receiving elements receiving the plurality of signal light beams of different wavelengths, wherein
the plurality of light-receiving elements are arranged in an end surface of a substrate in which the multiplex circuit is formed and receives the plurality of signal light beams of different wavelengths through the plurality of waveguides.
